(19) United States
(12) Patent Application Publication
(10) Pub. No.: US 2025/0088185 A1
(43) Pub. Date: Mar. 13, 2025

(54) SWITCHING CIRCUIT

(71) Applicants: KABUSHIKI KAISHA TOSHIBA, Tokyo (JP); Toshiba Electronic Devices & Storage Corporation, Tokyo (JP)

(72) Inventors: Yoshio Itagaki, Tokyo (JP); Takayuki Teraguchi, Kawasaki Kanagawa (JP)

(21) Appl. No.: 18/603,054

(22) Filed: Mar. 12, 2024

(30) Foreign Application Priority Data
Sep. 11, 2023 (JP) 2023-146961

(51) Int. Cl. H03K 17/687; H03H 7/38

(52) U.S. Cl. CPC H03K 17/687; H03H 7/38

(57) ABSTRACT

According to one embodiment, a switching circuit includes: a first terminal coupled to a first node; a first switch including a first end coupled to the first node and a second end coupled to a second node; a second switch and a first resistance coupled in parallel between the second node and a third node; a second terminal coupled to the third node; a third switch and a first inductor coupled in series between the second node and a ground; a fourth switch including a first end coupled to the first node and a second end coupled to a fourth node; a fifth switch and a second resistance coupled in parallel between the fourth node and a fifth node; a third terminal coupled to the fifth node; a sixth switch and a second inductor coupled in series between the fourth node and the ground.

### CROSS-REFERENCE TO RELATED APPLICATION

This application is based upon and claims the benefit of priority from Japanese Patent Application No. 2023-146961, filed Sep. 11, 2023, the entire contents of which are incorporated herein by reference.

### FIELD

Embodiments described herein relate generally to a switching circuit.

### BACKGROUND

A single-pole double-throw (SPDT) switch is known as a switch that transfers high-frequency signals. The SPDT switch selects only one of two individual terminals, and allows the selected individual terminal to be coupled to a common terminal to transfer high-frequency signals.

### BRIEF DESCRIPTION OF THE DRAWINGS

FIG. 1 is a block diagram showing an example of a configuration of a communication system including switching circuitry according to a first embodiment.

FIG. 2 is a circuit diagram showing an example of a configuration of switching circuitry according to the first embodiment.

FIG. 3 is a circuit diagram showing an example of an operating state of the switching circuitry according to the first embodiment.

FIG. 4 is a circuit diagram showing an example of equivalent circuitry of the switching circuitry and an individual functional circuit according to the first embodiment.

FIG. 5 is a graph showing an example of an insertion loss in the switching circuitry according to the first embodiment.

FIG. 6 is a graph showing an example of a maximum available power gain in the switching circuitry according to the first embodiment.

FIG. 7 is a graph showing an example of a return loss in the switching circuitry according to the first embodiment.

FIG. 8 is a circuit diagram showing an example of a configuration of switching circuitry according to a first modification of the first embodiment.

FIG. 9 is a circuit diagram showing an example of a configuration of switching circuitry according to a second embodiment.

FIG. 10 is a circuit diagram showing an example of a configuration of switching circuitry according to a third embodiment.

### DETAILED DESCRIPTION

In general, according to one embodiment, a switching circuit includes: a first terminal coupled to a first node; a first switch including a first end coupled to the first node and a second end coupled to a second node; a second switch and a first resistance coupled in parallel between the second node and a third node; a second terminal coupled to the third node; a third switch including a first end coupled to the second node; a first inductor including a first end coupled to a second end of the third switch and a second end that is grounded; a fourth switch including a first end coupled to the first node and a second end coupled to a fourth node; a fifth switch and a second resistance coupled in parallel between the fourth node and a fifth node; a third terminal coupled to the fifth node; a sixth switch including a first end coupled to the fourth node; and a second inductor including a first end coupled to a second end of the sixth switch and a second end that is grounded.

Hereinafter, embodiments will be described with reference to the accompanying drawings. In the description that follows, constituent elements having an approximately identical function and configuration will be assigned an identical symbol. If there is no need to mutually distinguish between elements represented by reference symbols including the same letters, these elements are denoted by reference symbols that include only the same letters.

In the description that follows, a first element being “coupled” to a second element encompasses a case where the first element is indirectly coupled to the second element via an intermediate element that is constantly or selectively conductive, or is directly coupled to the second element without intervention of an intermediate element.

In the description that follows, a state in which both ends of a switch are electrically coupled via the switch is referred to as an “on state”, and a state in which both ends are not electrically coupled via the switch is referred to as an “off state”.

### 1. First Embodiment

### 1.1 Overall Configuration

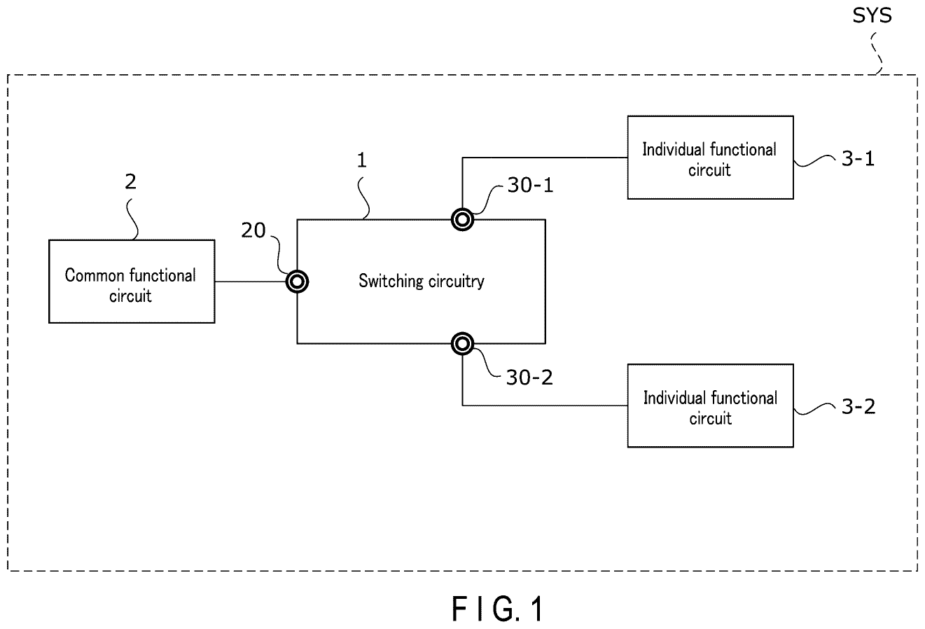

First, a first embodiment will be described. FIG. 1 is a block diagram showing an example of a configuration of a communication system including switching circuitry according to the first embodiment. A communication system SYS includes switching circuitry 1, a common functional circuit 2, and individual functional circuits 3-1 and 3-2. The communication system SYS is, for example, a transmission and reception system in wireless communications performed in a high-frequency band ranging from 600 MHz to 6 GHZ.

The switching circuitry 1 is formed on, for example, a silicon-on-insulator substrate (SOI). The switching circuitry 1 includes a common terminal 20 and individual terminals 30-1 and 30-2. The switching circuitry 1 is coupled to the common functional circuit 2, the individual functional circuit 3-1, and the individual functional circuit 3-2 via the common terminal 20, the individual terminal 30-1, and the individual terminal 30-2, respectively. The switching circuitry 1 selects one of the individual functional circuits 3-1 and 3-2, and electrically couples the common functional circuit 2 with the selected individual functional circuit. The non-selected individual functional circuit is electrically insulated from the common functional circuit 2. In response to an operation on the switching circuitry 1, the individual functional circuit that is electrically coupled to the common functional circuit 2 is switched. That is, the switching circuitry 1 functions as a single-pole double-throw (SPDT) switch.

The common functional circuit 2 is, for example, a transmission and reception antenna. The common functional circuit 2 receives a high-frequency signal from the exterior via wireless communications. Also, the common functional circuit 2 transmits a high-frequency signal to the exterior via wireless communications. The individual functional circuit 3-1 is, for example, a receiving unit, receives a high-frequency signal received via the transmission and reception antenna, and performs processing such as data reading. The individual functional circuit 3-2 is, for example, a transmitting unit, performs processing such as conversion of a high-frequency signal based on input data, passes the converted signal to the transmission and reception antenna, and transmits it to the exterior.

### 1.2 Configuration of Switching Circuitry

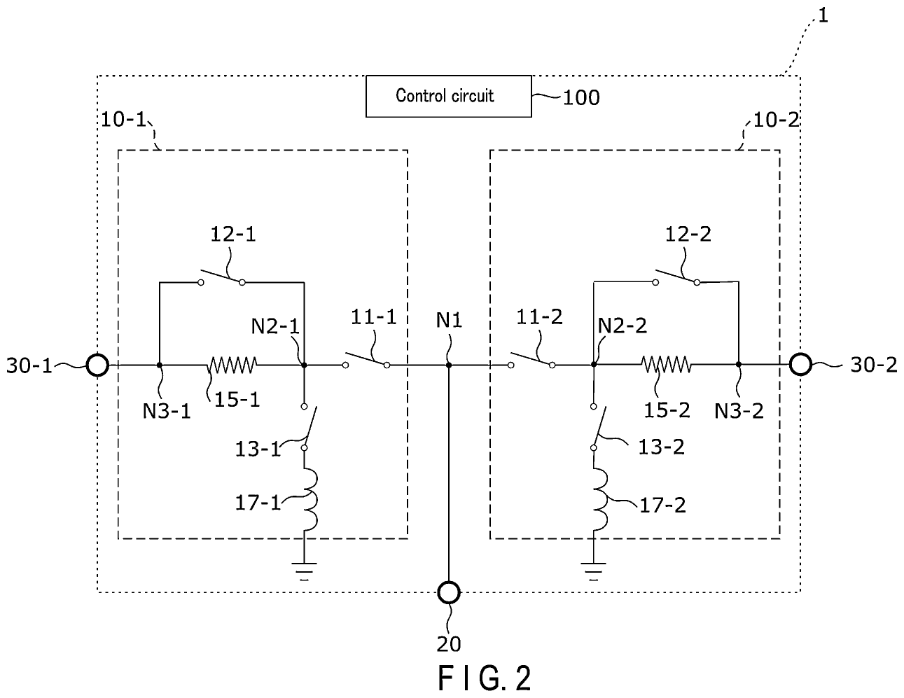

FIG. 2 is a circuit diagram showing an example of a configuration of switching circuitry according to the first embodiment. As shown in FIG. 2, the switching circuitry 1 further includes units 10-1 and 10-2, and a control circuit 100. The unit 10-1 is an internal circuit of the switching circuitry 1 configured to switch an electrical coupling state between the common terminal 20 and the individual terminal 30-1. The unit 10-2 is an internal circuit of the switching circuitry 1 configured to switch an electrical coupling state between the common terminal 20 and the individual terminal 30-2. The units 10-1 and 10-2 have substantially the same configuration.

The unit 10-1 includes switches 11-1, 12-1, and 13-1, a resistance 15-1, and an inductor 17-1. Each of the switches 11-1, 12-1, and 13-1 has a configuration in which a plurality of metal-oxide-semiconductor field-effect transistors (MOSFETs) whose gate electrodes are coupled to a common interconnect are coupled in series. The coupling state of each of the switches 11-1, 12-1, and 13-1 is switched by a control signal supplied from the control circuit 100 via an unillustrated interconnect.

The switch 11-1 includes a first end coupled to the common terminal 20 via a node N1 and a second end coupled to a node N2-1. The switch 12-1 includes a first end coupled to the node N2-1 and a second end coupled to the individual terminal 30-1 via a node N3-1. The switch 13-1 includes a first end coupled to the node N2-1 and a second end coupled to a first end of the inductor 17-1. The resistance 15-1 includes a first end coupled to the node N2-1 and a second end coupled to the individual terminal 30-1 via the node N3-1. The switch 12-1 and the resistance 15-1 are in a parallel relationship. A second end of the inductor 17-1 is grounded.

As seen from the individual terminal 30-1, an impedance of the resistance 15-1, the switch 12-1 in the off state, the switch 13-1 in the on state, and the inductor 17-1 is substantially equal to an internal impedance of the individual functional circuit 3-1. In the case where, for example, an internal resistance of 50 Ω is provided in the individual functional circuit 3-1, the sum of the resistance values of the resistance 15-1 and the on-state switch 13-1 is designed to be 50 Ω.

Note that, if the switching circuitry 1 is operated in a high-frequency band, an electric power on the order of, for example, 25 dBm may be input to the individual terminal 30-1 in the case of electrical insulation between the common terminal 20 and the individual terminal 30-1 by the unit 10-1. The unit 10-1 is designed so as not to be destroyed by the electric power input to the individual terminal 30-1. Specifically, the resistance 15-1 may have, for example, a physical size equal to or greater than 10000 μm². Also, the switch 12-1 may have a configuration in which, for example, three or more MOSFETs each having a gate width on the order of 4 mm are coupled in series. In this case, the switch 12-1 in the off state may have a capacitance on the order of 0.4 pF. A change in the impedance caused by the capacitance of the off-state switch 12-1, which cannot be disregarded in the high-frequency band, is compensated for by the inductor 17-1.

The unit 10-2 includes switches 11-2, 12-2, and 13-2, a resistance 15-2, and an inductor 17-2. Each of the switches 11-2, 12-2, and 13-2 includes a plurality of MOSFETs coupled in series. The coupling state of each of the switches 11-2, 12-2, and 13-2 is switched by a control signal supplied from the control circuit 100 via an unillustrated interconnect.

The switch 11-2 includes a first end coupled to the common terminal 20 via a node N1 and a second end coupled to a node N2-2. The switch 12-2 includes a first end coupled to the node N2-2 and a second end coupled to the individual terminal 30-2 via a node N3-2. The switch 13-2 includes a first end coupled to the node N2-2 and a second end coupled to a first end of the inductor 17-2. The resistance 15-2 includes a first end coupled to the node N2-2 and a second end coupled to the individual terminal 30-2 via the node N3-2. The switch 12-2 and the resistance 15-2 are in a parallel relationship. A second end of the inductor 17-2 is grounded.

As seen from the individual terminal 30-2, an impedance of the resistance 15-2, the switch 12-2 in the off state, the switch 13-2 in the on state, and the inductor 17-2 is substantially equal to an impedance of the individual functional circuit 3-2. In the case where, for example, an internal resistance of 50 Ω is provided in the individual functional circuit 3-2, the sum of the resistance values of the resistance 15-2 and the on-state switch 13-2 is designed to be 50 Ω.

Note that, if the switching circuitry 1 is operated in a high-frequency band, an electric power on the order of, for example, 25 dBm may be input to the individual terminal 30-2 in the case of electrical insulation between the common terminal 20 and the individual terminal 30-2 by the unit 10-2. The unit 10-2 is designed so as not to be destroyed by the electric power input to the individual terminal 30-2. Specifically, the resistance 15-2 may have, for example, a physical size equal to or greater than 10000 μm². Also, the switch 12-2 may have a configuration in which, for example, three or more MOSFETs each having a gate width on the order of 4 mm are coupled in series. In this case, the switch 12-2 in the off state may have a capacitance on the order of 0.4 pF. A change in the impedance caused by the capacitance of the off-state switch 12-2, which cannot be disregarded in the high-frequency band, is compensated for by the inductor 17-2.

The control circuit 100 sends a control signal to each of the switches 11-1, 12-1, 13-1, 11-2, 12-2, and 13-2, thereby controlling the switches. Specifically, by applying voltages with different levels to the switches via an unillustrated interconnect, the electrical coupling state between each of the individual functional circuits 3-1 and 3-2 and the common functional circuit 2 is switched.

### 1.3 Operation of Switching Circuitry

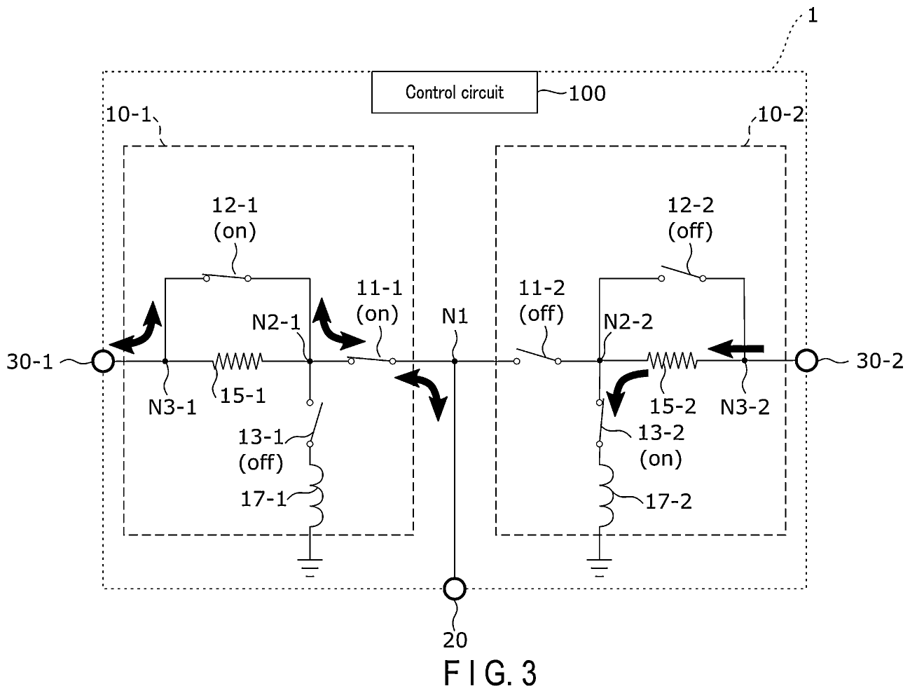

FIG. 3 is a circuit diagram showing an example of an operating state of the switching circuitry according to the first embodiment. The operating state shown in FIG. 3 corresponds to a state in an operation in which a signal is conveyed between the common terminal 20 and the individual terminal 30-1, and the individual terminal 30-2 is terminated. That is, in FIG. 3, a case is shown where the individual terminal 30-1 is electrically coupled to the common terminal 20, and the individual terminal 30-2 is electrically insulated from the common terminal 20. Note that the arrows in FIG. 3 represent a major conveyance path of a high-frequency signal input from each terminal.

The state of each switch in the case where the common terminal 20 and the individual terminal 30-1 are coupled and the conveyance path of a high-frequency signal input from each terminal as shown in FIG. 3 will be described.

In the unit 10-1, the switches 11-1, 12-1, and 13-1 are brought to the on state, the on state, and the off state, respectively. Thereby, the high-frequency signal input from the common terminal 20 passes through the switches 11-1 and 12-1, and is conveyed to the individual terminal 30-1, as shown by the arrows in FIG. 3. The same applies to the case where a high-frequency signal is conveyed from the individual terminal 30-1 to the common terminal 20.

In the unit 10-2, the switch 11-2 is brought to the off state. Thereby, conveyance of a high-frequency signal between the common terminal 20 and the individual terminal 30-2 is interrupted. Also, the switch 12-2 is brought to the off state, and the switch 13-2 is brought to the on state. Thereby, the individual terminal 30-2 is terminated via the resistance 15-2, the on-state switch 13-2, and the inductor 17-2.

Note that, in the case where the common terminal 20 and the individual terminal 30-2 are electrically coupled, coupling states of switches corresponding to the units 10-1 and 10-2 are inverted (illustration is omitted). That is, the switches 11-2, 12-2, and 13-1 are brought to the on state, and the switches 11-1, 12-1, and 13-2 are brought to the off state. In this case, conveyance of a high-frequency signal between the common terminal 20 and the individual terminal 30-1 is interrupted, and the individual terminal 30-1 is terminated via the resistance 15-1, the on-state switch 13-1, and the inductor 17-1.

### 1.4 Effects of First Embodiment

According to the first embodiment, it is possible to reduce an insertion loss of a high-frequency signal conveyed between terminals. Also, it is possible to reduce a return loss of a high-frequency signal input from an individual terminal which is not coupled to a common terminal. Such effects will be described in detail below.

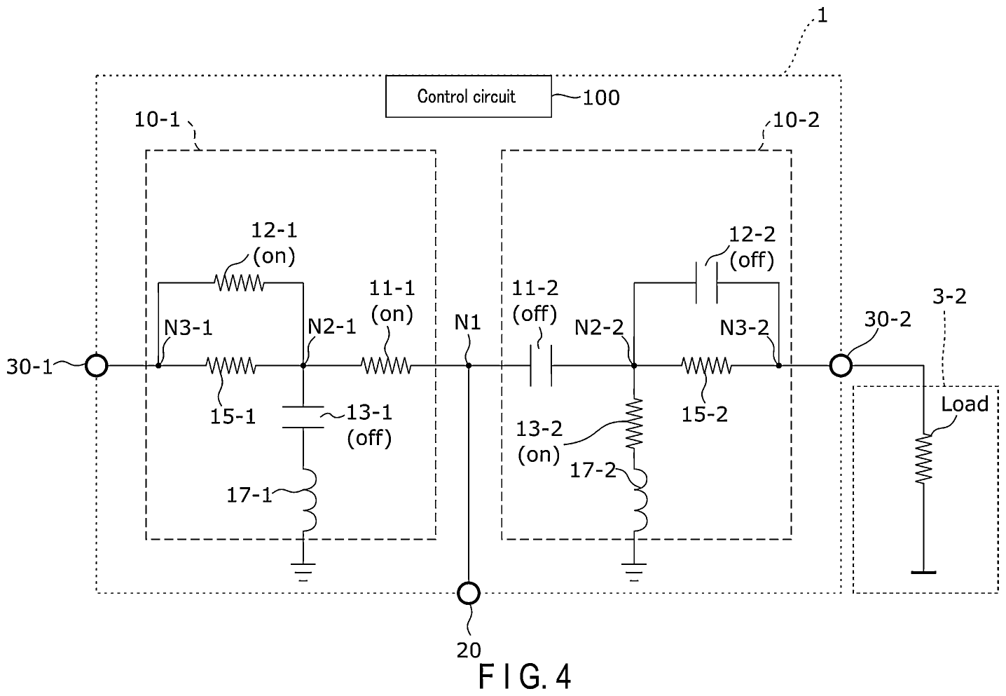

In the switching circuitry 1 according to the first embodiment, the resistance 15-2 is provided between the switch 11-2 and the individual terminal 30-2. Thereby, in the case where a signal is conveyed between the common terminal 20 and the individual terminal 30-1, an impedance mismatch occurs between the impedance of the side of the node N2-2 as seen from the switch 11-2 in the off state and the impedance of the side of the node N1 as seen from the switch 11-2 in the off state. Thus, a signal conveyed between the common terminal 20 and the individual terminal 30-1 is reflected by the off-state switch 11-2, and an insertion loss of the signal is reduced. Similarly, the resistance 15-1 is provided between the switch 11-1 and the individual terminal 30-1. Thereby, in the case where a signal is conveyed between the common terminal 20 and the individual terminal 30-2, an impedance mismatch occurs between the impedance of the side of the node N2-1 as seen from the switch 11-1 in the off state and the impedance of the side of the node N1 as seen from the switch 11-1 in the off state. Thus, a signal conveyed between the common terminal and the individual terminal 30-2 is reflected by the off-state switch 11-1, and an insertion loss of the signal is reduced. This effect will be described with reference to FIGS. 4, 5, and 6.

FIG. 4 is a circuit diagram showing an example of equivalent circuitry of the switching circuitry and the individual functional circuit according to the first embodiment. In FIG. 4, equivalent circuitry of the switching circuitry 1 and the individual functional circuit 3-2 in the coupling state shown in FIG. 3 is shown. In FIG. 4, on-state switches and off-state switches are regarded as being equivalent to resistances and capacitors, respectively, and are substituted as such. An individual functional circuit 3-2 includes therein a load resistance Load. The load resistance Load has an impedance of, for example, 50 Ω.

As shown in FIG. 4, in the case where an individual terminal 30-1 is electrically coupled to a common terminal 20, switches 11-2 and 12-2 are brought to the off state, and a switch 13-2 is brought to the on state. Both of the switch 13-2 and an inductor 17-2 have a small impedance. Thus, the impedance of a circuit on the side of the node N2-2 as seen from the off-state switch 11-2 is sufficiently small, and is, for example, less than 25 Ω.

On the other hand, in the case where a signal is conveyed between the common terminal 20 and the individual terminal 30-1, the impedance of a circuit on the side of a node N1 as seen from the off-state switch 11-2 is on the order of, for example, 25 Ω. Thus, as seen from the switch 11-2, an impedance mismatch occurs between the circuit on the node N1 side and the circuit on the node N2-2 side. As a result, a high-frequency signal that has passed through the switch 11-2 is reflected in the vicinity of the node N2-2, and returns to a correct circuit direction (from the common terminal 20 to the individual terminal 30-1, or vice versa). With such an effect, it is possible to reduce an insertion loss involved with a high-frequency signal flowing to the side of the unit 10-2. Also, in the case where a common terminal 20 and the individual terminal 30-2 are electrically coupled, with the effect of a high-frequency signal that has passed through a switch 11-1 being reflected in the vicinity of the node N2-1, it is similarly possible to reduce an insertion loss (illustration is omitted).

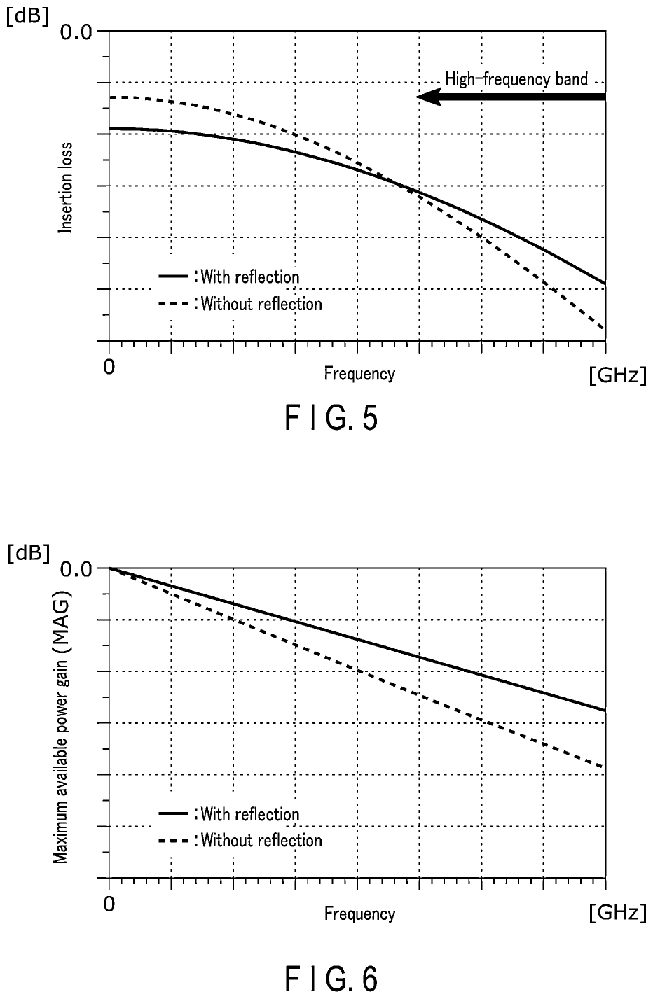

FIG. 5 is a graph showing an example of an insertion loss in the switching circuitry according to the first embodiment. In FIG. 5, an insertion loss of the switching circuitry 1 in the coupling state shown in FIG. 3 is shown by a solid line. Also, in FIG. 5, an insertion loss of switching circuitry in which reflection does not occur in the coupling state shown in FIG. 3 is shown by a dotted line as a comparative example. The switching circuitry according to the comparative example corresponds to, for example, the case where the resistance 15-2 is coupled between the switch 13-2 and the ground.

As shown in FIG. 5, in conveying a signal in a high-frequency band, the insertion loss is comparatively reduced in a circuit configuration in which reflection occurs.

FIG. 6 is a graph showing an example of a maximum available power gain (MAG) in the switching circuitry according to the first embodiment. In FIG. 6, a maximum available power gain of the switching circuitry 1 in the coupling state of FIG. 3 is shown by a solid line. Also, in FIG. 6, a maximum available power gain of switching circuitry in which reflection does not occur in the coupling state of FIG. 3 is shown by a dotted line as a comparative example.

As shown in FIG. 6, a circuit configuration in which reflection occurs constantly provides a greater maximum available power gain, with the difference becoming more noticeable as the frequency increases.

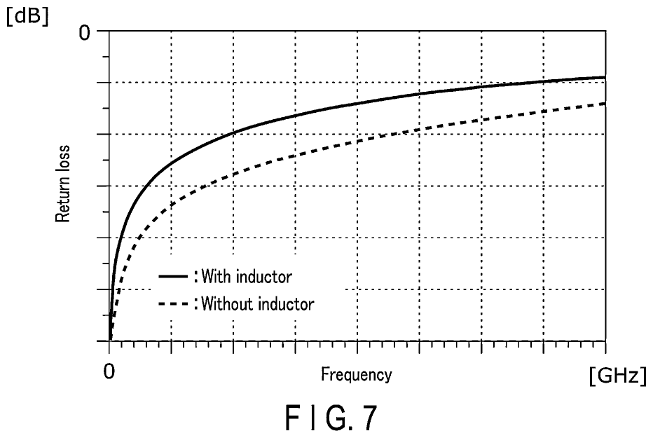

Furthermore, in the switching circuitry 1 according to the first embodiment, the inductor 17-2 is provided between the switch 13-2 and the ground. Thereby, in the case where the individual terminal 30-2 is insulated from the common terminal 20, an impedance matching occurs between the side of the individual functional circuit 3-2 as seen from the individual terminal 30-2, and the side of the node N3-2 as seen from the individual terminal 30-2. Thus, a signal issued from the individual functional circuit 3-2 is not easily reflected in the vicinity of the individual terminal 30-2, causing a reduction in the return loss of the signal. Similarly, the inductor 17-1 is provided between the switch 13-1 and the ground. Thereby, in the case where the individual terminal 30-1 is insulated from the common terminal 20, an impedance matching occurs between the side of the individual functional circuit 3-1 as seen from the individual terminal 30-1, and the side of the node N3-1 as seen from the individual terminal 30-1. Thus, a signal issued from the individual functional circuit 3-1 is not easily reflected in the vicinity of the individual terminal 30-1, causing a reduction in the return loss of the signal. This effect will be described with reference to FIGS. 4 and 7.

As shown in FIG. 4, in the case where the individual terminal 30-2 is insulated from the common terminal 20, the switches 11-2 and 12-2 are brought to the off state, and the switch 13-2 is brought to the on state. The impedance on the side of the switch 11-2 in the off state as seen from the node N2-2 is sufficiently greater than the impedance on the side of the switch 13-2 as seen from the node N2-2. Thus, assuming a path of a signal input from the individual terminal 30-2, the circuit on the side of the switch 11-2 as seen from the node N2-2 can be disregarded.

Let us assume an impedance of a circuit in which a signal input from the individual terminal 30-2 bypasses the unit 10-2, and is coupled to the ground and terminated. In this case, since a change in the impedance caused by the capacitance of the off-state switch 12-2 is compensated for by the inductor 17-2, the impedance of such a circuit takes substantially the same value as the impedance of the load resistance Load included in the individual functional circuit 3-2 (e.g., 50 22). Thus, as seen from the individual terminal 30-2, an impedance match occurs between the circuit on the side of the individual functional circuit 3-2 and the circuit on the side of the unit 10-2. With such an effect, it is possible to optimize signal conveyance efficiency from the individual terminal 30-2 to the unit 10-2, thereby reducing a return loss at the circuit boundary. Also, in the case where the common terminal 20 and the individual terminal 30-2 are electrically coupled, an impedance match similarly occurs between the circuit on the side of the individual functional circuit 3-1 and the circuit on the side of the unit 10-1 (illustration is omitted). With such an effect, it is possible to optimize signal conveyance efficiency from the individual terminal 30-1 to the unit 10-1, thereby reducing a return loss at the circuitry boundary.

FIG. 7 is a graph showing an example of a return loss in the switching circuitry according to the first embodiment. In FIG. 7, a return loss of the switching circuitry 1 in the coupling state of FIG. 3 is shown by a solid line. Also, in FIG. 7, a return loss of switching circuitry not including an inductor 17-2 in the coupling state of FIG. 3 is shown by a dotted line as a comparative example.

As shown in FIG. 7, the return loss is comparatively reduced in the circuit configuration including the inductor 17-2.

### 1.5 First Modification

The above-described switching circuitry 1 according to the first embodiment may be modified in various manners. Hereinafter, features different from those of the first embodiment will be mainly described.

A communication system SYS including switching circuitry 1A according to the first modification includes n individual functional circuits 3-1, 3-2, . . . , and 3-n (where n is an integer equal to or greater than three). The communication system SYS is, for example, a transmission and reception system capable of processing high-frequency signals with different frequencies in high-frequency signal wireless communications. The n individual functional circuits 3-1, 3-2, . . . , and 3-n are, for example, either receiving units or transmitting units, and respectively correspond to different frequencies. The switching circuitry 1A electrically couples the common functional circuit 2 with one of the individual functional circuits 3-i (i∈{1, 2, . . . , n}) that has been selected, and electrically insulates the common functional circuit 2 from the non-selected individual functional circuits 3-j (j≠i; j∈{1, 2, . . . , n}). That is, the switching circuitry 1A functions as a single-pole n-throw (SPnT) switch. The switching circuitry 1A includes n individual function terminals 30-1, 30-2, . . . , and 30-n. Each of the n individual function terminals 30-1, 30-2, . . . , and 30-n is coupled to the n individual functional circuits 3-1, 3-2, . . . , and 3-n, respectively.

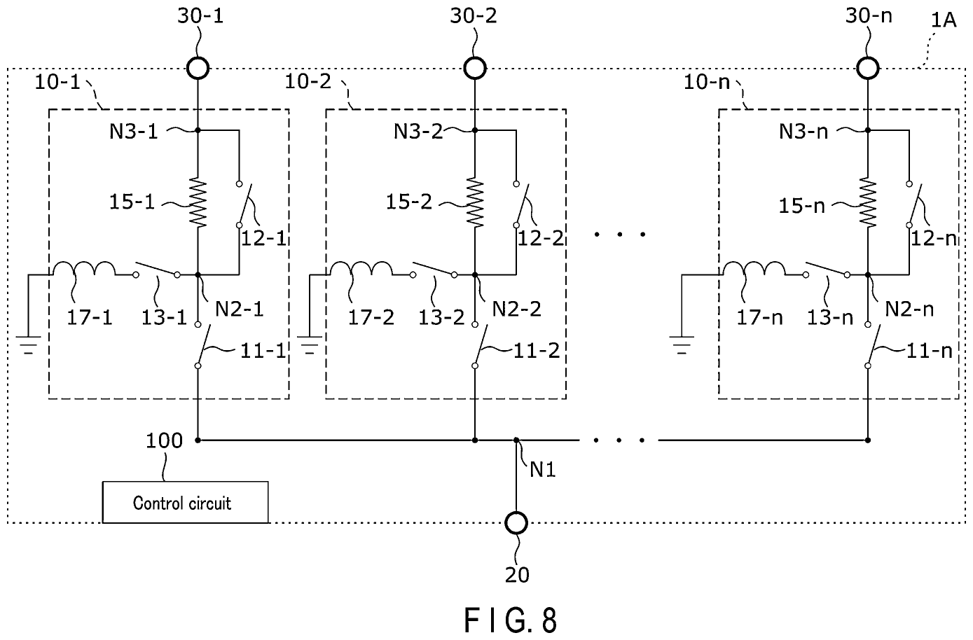

FIG. 8 is a circuit diagram showing an example of a configuration of switching circuitry according to the first modification of the first embodiment. The switching circuitry 1A switches between the common terminal and the n individual terminals. As shown in FIG. 8, the switching circuitry 1A includes units 10-1, 10-2, . . . , and 10-n. The units 10-1, 10-2, . . . , and 10-n are coupled in parallel to a node N1 that receives an interconnect extending from a common terminal 20.

Each of the units 10-1, 10-2, . . . , and 10-n has substantially the same configuration as the units 10-1 and 10-2 in the first embodiment.

The unit 10-n includes, for example, switches 11-n, 12-n, and 13-n, a resistance 15-n, and an inductor 17-n. Each of the switches 11-n, 12-n, and 13-n include, for example, a configuration in which a plurality of MOSFETS whose gate electrodes are coupled to a common interconnect are coupled in series. The coupling state of each of the switches 11-n, 12-n, and 13-n is switched by a control signal supplied from the control circuit 100 via an unillustrated interconnect.

The switch 11-n includes a first end coupled to the common terminal 20 via the node N1 and a second end coupled to a node N2-n. The switch 12-n includes a first end coupled to the node N2-n and a second end coupled to an individual terminal 30-n via a node N3-n. The switch 13-n includes a first end coupled to the node N2-n and a second end coupled to a first end of the inductor 17-n. The resistance 15-n includes a first end coupled to the node N2-n and a second end coupled to the individual terminal 30-n via the node N3-n. The switch 12-n and the resistance 15-n are in a parallel relationship. A second end of the inductor 17-n is grounded.

As seen from the individual terminal 30-n, an impedance of the resistance 15-n, the switch 12-n in the off state, the switch 13-n in the on state, and the inductor 17-n is substantially equal to an impedance of the individual functional circuit 3-n. In the case where, for example, an internal resistance of 50 Ω is provided in the individual functional circuit 3-n, the sum of the resistance values of the resistance 15-n and the on-state switch 13-n is designed to be 50 Ω.

The control circuit 100 controls switches (11-1, 12-1, 13-1, 11-2, 12-2, 13-2,., 11-n, 12-n, and 13-n) included in the switching circuitry 1. Specifically, by applying voltages with different levels to the switches via an unillustrated interconnect, the electrical coupling state between each of the individual functional circuits 3-1, 3-2, . . . , and 3-n and the common functional circuit 2 is switched.

In the case where the switching circuitry 1A electrically couples the common terminal 20 and one of the individual terminals 30-i that has been selected (i∈{1, 2, . . . , n}), the unit 10-i will be configured in such a manner that the switches 11-i and 12-i are brought to the on state and the switch 13-i is brought to the off state. A given other unit 10-j (j≠i; j∈{1, 2, . . . , n}) is configured in such a manner that the switches 11-j and 12-j are brought to the off state, and the switch 13-j is brought to the on state. Thereby, signal conveyance between the common terminal 20 and the selected individual terminal 30-i and termination any of the given non-selected individual terminal 30-j are achieved.

With the configuration according to the first modification, it is possible to switch to three or more individual functional terminals with respect to a single common functional terminal.

### 2. Second Embodiment

Next, a second embodiment will be described. Hereinafter, configurations different from those of the first embodiment will be mainly described.

### 2.1 Configuration of Switching Circuitry

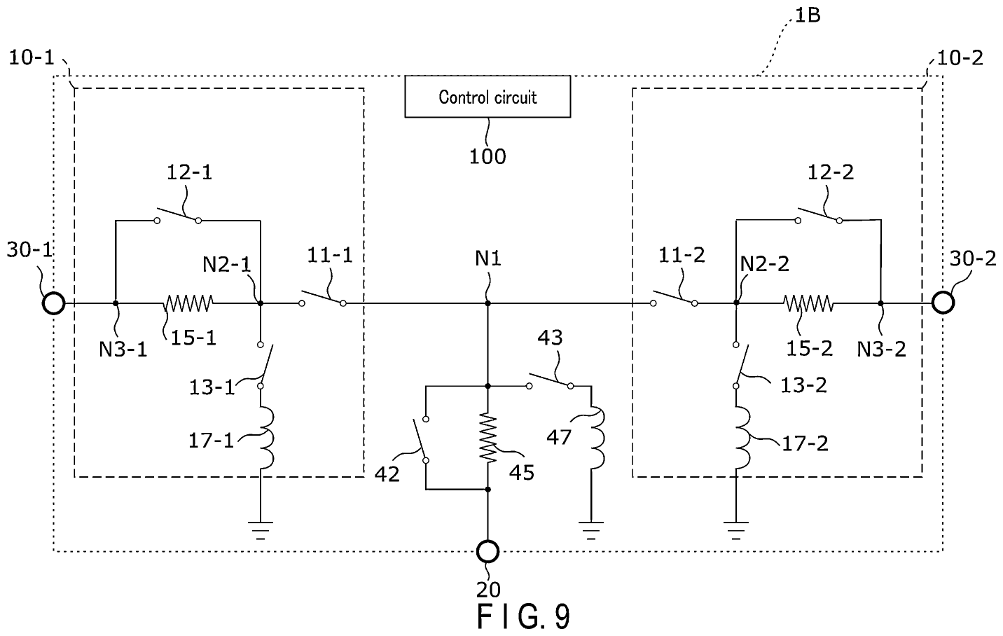

FIG. 9 is a circuit diagram showing an example of a configuration of switching circuitry 1B according to the second embodiment. The switching circuitry 1B includes, in addition to the configuration of the switching circuitry 1 according to the first embodiment, switches 42 and 43, a resistance 45, and an inductor 47. Each of the switches 42 and 43 may include a configuration in which a plurality of MOSFETs whose gate electrodes are coupled to a common interconnect are coupled in series. The coupling state of each of the switches 42 and 43 is switched by a control signal supplied from the control circuit 100 via an unillustrated interconnect.

The switch 42 is arranged between the common terminal 20 and the node N1. That is, the switch 42 includes a first end coupled to the common terminal 20 and a second end coupled to the node N1. The switch 43 includes a first end coupled to the node N4 and a second end coupled to a first end of the inductor 47. The resistance 45 includes a first end coupled to the common terminal 20 and a second end coupled to the node N1. The switch 42 and the resistance 45 are in a parallel relationship. A second end of the inductor 47 is grounded.

As seen from the common terminal 20, an impedance of the resistance 45, the switch 42 in the off state, the switch 43 in the on state, and the inductor 47 is substantially equal to an impedance of the common functional circuit 2. In the case where, for example, an internal resistance of 50 Ω is provided in the common functional circuit 2, the sum of the resistance values of the resistance 45 and the on-state switch 43 is designed to be 50 Ω.

In the case where the common terminal 20 is electrically coupled to the individual terminal 30-1 or 30-2, the switch 42 is brought to the on state, and the switch 43 is brought to the off state. Thereby, a high-frequency signal input from the common terminal 20 passes through the switch 42 and is conveyed to the node N1, and is further conveyed to the individual terminal 30-1 or 30-2. The same applies to the case where a high-frequency signal is conveyed from the individual terminal 30-1 or 30-2 to the common terminal 20.

In the case where the common terminal 20 is electrically insulated from any of the other terminals, the switch 42 is brought to the off state, and the switch 43 is brought to the on state. Also, both of the switch 11-1 of the unit 10-1 and the switch 11-2 of the unit 10-2 are brought to the off state. Thereby, a high-frequency signal flowing from the common terminal 20 is terminated via the resistance 45, the on-state switch 43, and the inductor 47.

### 2.2 Effects of Second Embodiment

According to the second embodiment, similarly to the first embodiment, in the case where a signal is conveyed between the common terminal 20 and the individual terminal 30-1, since an impedance mismatch occurs in the off-state switch 11-2 and causes the signal to be reflected, it is possible to reduce a high-frequency signal insertion loss. In the case where a signal is conveyed between the common terminal 20 and the individual terminal 30-2, since an impedance mismatch occurs in the off-state switch 11-1 and causes the signal to be reflected, it is possible to reduce a high-frequency signal insertion loss. Also, in the case where the individual terminal 30-2 is insulated from the common terminal 20, since an impedance match occurs at the individual terminal 30-2, and a signal issued from the individual functional circuit 3-2 is not easily reflected in the vicinity of the individual terminal 30-2, it is possible to reduce a return loss of the signal. In the case where the individual terminal 30-1 is insulated from the common terminal 20, since an impedance match occurs at the individual terminal 30-1, and the signal issued from the individual functional circuit 3-1 is not easily reflected in the vicinity of the individual terminal 30-1, it is possible to reduce a return loss of the signal.

Furthermore, according to the second embodiment, in the case where the common terminal 20 is electrically insulated from either of the individual terminals 30-1 and 30-2, the common terminal 20 can be terminated. Also, in the case where the common terminal 20 is terminated, it is possible to reduce a return loss of a high-frequency signal issued from the common terminal 20.

### 2.3 Second Modification

As a modification (second modification) of the above-described switching circuitry 1B, an SPnT switch in which a single common functional circuit is coupled to a plurality of individual functional circuits, as in the first modification, may be conceivable. With the configuration according to the second modification, it is possible to switch to three or more individual functional terminals with respect to a single common functional terminal.

### 3. Third Embodiment

Next, a third embodiment will be described. Hereinafter, configurations different from those of the first embodiment will be mainly described.

### 3.1 Configuration of Switching Circuitry

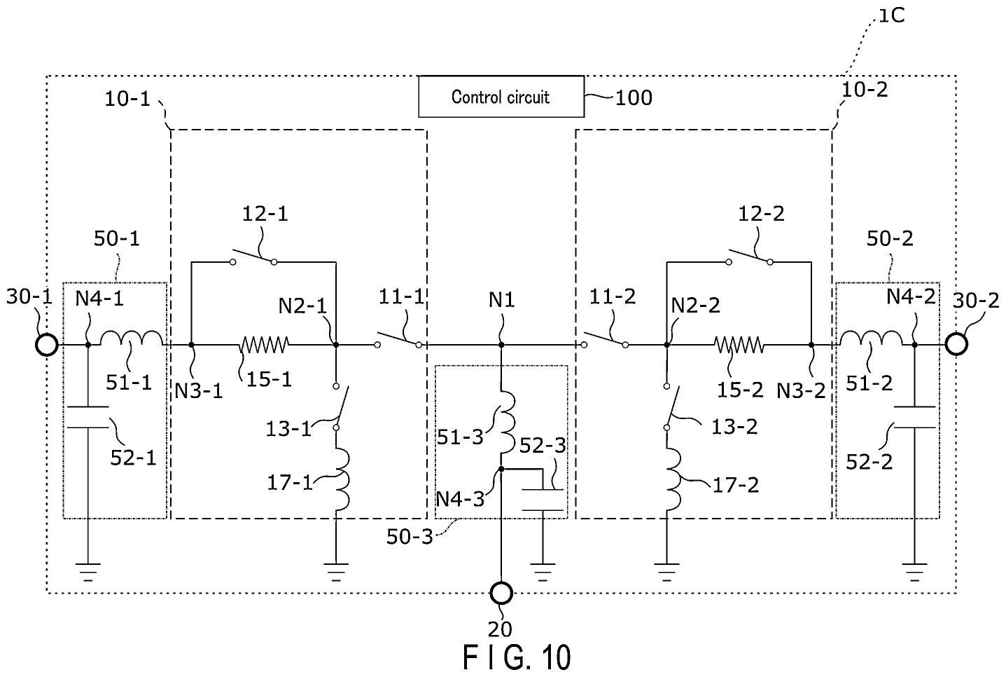

FIG. 10 is a circuit diagram showing an example of a configuration of switching circuitry 1C according to the third embodiment. The switching circuitry 1C further includes, in addition to the configuration of the switching circuitry 1 according to the first embodiment, circuits 50-1, 50-2, and 50-3. Each of the circuits 50-1, 50-2, and 50-3 is a circuit equipped with a function of adjusting an impedance in the switching circuitry 1C, and configured to inhibit an impedance mismatch caused by signal deterioration such as an insertion loss.

The circuit 50-1 is coupled between the unit 10-1 and the individual terminal 30-1. The circuit 50-1 includes an inductor 51-1 and a capacitor 52-1. The inductor 51-1 includes a first end coupled to the node N3-1 and a second end coupled to the individual terminal 30-1 via the node N4-1. The capacitor 52-1 includes a first end coupled to the node N4-1 and a second end that is grounded.

The circuit 50-2 is coupled between the unit 10-2 and the individual terminal 30-2. The circuit 50-2 includes an inductor 51-2 and a capacitor 52-2. The inductor 51-2 includes a first end coupled to the node N3-2 and a second end coupled to the individual terminal 30-2 via the node N4-2. The capacitor 52-2 includes a first end coupled to the node N4-2 and a second end that is grounded.

The circuit 50-3 is coupled between the common terminal 20 and the node N1. The circuit 50-3 includes an inductor 51-3 and a capacitor 52-3. The inductor 51-3 includes a first end coupled to the node N1 and a second end coupled to the common terminal 20 via the node N4-3. The capacitor 52-3 includes a first end coupled to the node N4-3 and a second end that is grounded.

### 3.2 Effects of Third Embodiment

With the configuration according to the third embodiment, similarly to the first embodiment, in the case where a signal is conveyed between the common terminal 20 and the individual terminal 30-1, since an impedance mismatch occurs in the off-state switch 11-2 and causes the signal to be reflected, it is possible to reduce a high-frequency signal insertion loss. In the case where a signal is conveyed between the common terminal 20 and the individual terminal 30-2, since an impedance mismatch occurs in the off-state switch 11-1 and causes the signal to be reflected, it is possible to reduce a high-frequency signal insertion loss. Also, in the case where the individual terminal 30-2 is insulated from the common terminal 20, since an impedance match occurs at the individual terminal 30-2, and a signal issued from the individual functional circuit 3-2 is not easily reflected in the vicinity of the individual terminal 30-2, it is possible to reduce a return loss of the signal. In the case where the individual terminal 30-1 is insulated from the common terminal 20, since an impedance match occurs at the individual terminal 30-1, and the signal issued from the individual functional circuit 3-1 is not easily reflected in the vicinity of the individual terminal 30-1, it is possible to reduce a return loss of the signal.

Furthermore, with the configuration according to the third embodiment, it is possible to reduce a return loss of a signal input from a functional circuit that is insulated from another functional circuit. Such effects will be described in detail below.

Let us assume a circuit with the configuration according to the third embodiment in which, in the case where the individual terminal 30-2 is insulated from the common terminal 20, a signal input from the individual terminal 30-2 is terminated. Since the circuit 50-2 is coupled between the unit 10-2 and the individual terminal 30-2, it is possible to finely adjust an impedance of the circuit including the switches 12-2 and 13-2, the resistance 15-2, the inductor 17-2, and the circuit 50-2. Thus, the impedance of the circuit on the side of the unit 10-2 as seen from the individual functional circuit 3-2 can be adjusted to match the impedance of the load resistance Load included in the individual functional circuit 3-2, with the phases also corrected. As a result, an impedance match occurs between a characteristic impedance of a signal input from the individual functional circuit 3-2 and an impedance of a circuit that terminates the individual terminal 30-2, thus preventing the reflection from occurring at the circuit boundary, and reducing a return loss. In the case where the common terminal 20 and the individual terminal 30-1 are insulated, by letting a signal input from the individual terminal 30-1 to the unit 10-1 bypass the circuit 50-1, an impedance match similarly occurs, further reducing a return loss at the circuit boundary.

Also, by letting a signal input from the common terminal 20 bypass the circuit 50-3, it is possible to finely adjust the impedance, and to cause an impedance match. As a result, it is possible to optimize signal conveyance efficiency from the common terminal 20 to the unit 10-1 or 10-2, thereby reducing a return loss.

### 3.3 Third Modification

As a modification (third modification) of the above-described switching circuitry 1C, an SPnT switch in which a single common functional circuit is coupled to a plurality of individual functional circuits, as in the first modification, is conceivable. With the configuration according to the third modification, it is possible to switch to three or more individual functional terminals with respect to a single common functional terminal.

### 4. Others

In the above-described third embodiment, a case has been described where the circuits 50-1, 50-2, and 50-3 are applied to the switching circuitry 1 according to the first embodiment; however, the configuration is not limited thereto. For example, circuits 50-1, 50-2, and 50-3 may be applied to the switching circuitry 1B according to the second embodiment.

In the above-described third embodiment, a configuration in which the impedance matching circuit 50-1 includes both the inductor 51-1 and the capacitor 52-1 has been described; however, the configuration is not limited thereto. For example, a configuration in which a circuit 50-1 includes at least one of the inductor 51-1 or the capacitor 52-1 may be adopted.

In the above-described third embodiment, a configuration in which the circuit 50-2 includes both the inductor 51-2 and the capacitor 52-2 has been described; however, the configuration is not limited thereto. For example, a configuration in which a circuit 50-2 includes at least one of the inductor 51-2 or the capacitor 52-2 may be adopted.

In the above-described third embodiment, a configuration in which the circuit 50-3 includes both the inductor 51-3 and the capacitor 52-3 has been described; however, the configuration is not limited thereto. For example, a configuration in which a circuit 50-3 includes at least one of the inductor 51-3 or the capacitor 52-3 may be adopted.

Also, in the above-described third embodiment, a configuration in which the switching circuitry 1C includes all of the circuits 50-1, 50-2, and 50-3 have been described; however, the configuration is not limited thereto. For example, the switching circuitry 1C may have a configuration in which at least one of the circuits 50-1, 50-2, and 50-3 is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A switching circuit, comprising:
a first terminal coupled to a first node;
a first switch including a first end coupled to the first node and a second end coupled to a second node;
a second switch and a first resistance coupled in parallel between the second node and a third node;
a second terminal coupled to the third node;
a third switch including a first end coupled to the second node;
a first inductor including a first end coupled to a second end of the third switch and a second end that is grounded;
a fourth switch including a first end coupled to the first node and a second end coupled to a fourth node;
a fifth switch and a second resistance coupled in parallel between the fourth node and a fifth node;
a third terminal coupled to the fifth node;
a sixth switch including a first end coupled to the fourth node; and
a second inductor including a first end coupled to a second end of the sixth switch and a second end that is grounded.

2. The switching circuit according to claim 1, wherein
one of the second terminal or the third terminal that has been selected is electrically coupled to the first terminal.

3. The switching circuit according to claim 1, wherein
a signal that has been input or output from the first terminal, the second terminal, or the third terminal has a frequency equal to or higher than 600 MHz and equal to or lower than 6 GHz.

4. The switching circuit according to claim 1, wherein
each of the first switch, the second switch, the third switch, the fourth switch, the fifth switch, and the sixth switch includes a plurality of transistors coupled in series.

5. The switching circuit according to claim 3, wherein
an amount of increase in an impedance of the circuitry in which the signal has been allowed to flow through the first inductor is substantially equal to an amount of decrease in an impedance of the circuitry in which the signal has been allowed to flow through the first resistance and the second switch in an off state, which are coupled in parallel, as compared to an impedance of the circuitry in which the signal has been allowed to flow through the first resistance only, and
an amount of increase in an impedance of the circuitry in which the signal has been allowed to flow through the second inductor is substantially equal to an amount of decrease in an impedance of the circuitry in which the signal has been allowed to flow through the second resistance and the fifth switch in an off state, which are coupled in parallel, as compared to an impedance of the circuitry in which the signal has been allowed to flow through the second resistance only.

6. The switching circuit according to claim 1, further comprising:
a control circuit, wherein
the control circuit is configured to:
bring, in a first operation, the first switch, the second switch, and the sixth switch to an on state, and the third switch, the fourth switch, and the fifth switch to an off state; and
bring, in a second operation, the third switch, the fourth switch, and the fifth switch to an on state, and the first switch, the second switch, and the sixth switch to an off state.

7. The switching circuit according to claim 6, wherein
an impedance on a side of the first node mismatches an impedance on a side of the fourth node as seen from the fourth switch during the first operation, and
an impedance on a side of the first node mismatches an impedance on a side of the second node as seen from the first switch during the second operation.

8. The switching circuit according to claim 1, further comprising:
a seventh switch and a third resistance coupled in parallel between the first terminal and the first node;
an eighth switch including a first end coupled to the first node; and
a third inductor including a first end coupled to a second end of the eighth switch and a second end that is grounded.

9. The switching circuit according to claim 8, wherein
a signal that has been input or output from the first terminal, the second terminal, or the third terminal has a frequency equal to or higher than 600 MHz and equal to or lower than 6 GHz.

10. The switching circuit according to claim 8, wherein
each of the first switch, the second switch, the third switch, the fourth switch, the fifth switch, the sixth switch, the seventh switch, and the eighth switch includes a plurality of transistors coupled in series.

11. The switching circuit according to claim 9, wherein
an amount of increase in an impedance of the circuitry in which the signal has been allowed to flow through the first inductor is substantially equal to an amount of decrease in an impedance of the circuitry in which the signal has been allowed to flow through the first resistance and the second switch in an off state, which are coupled in parallel, as compared to an impedance of the circuitry in which the signal has been allowed to flow through the first resistance only,
an amount of increase in an impedance of the circuitry in which the signal has been allowed to flow through the second inductor is substantially equal to an amount of decrease in an impedance of the circuitry in which the signal has been allowed to flow through the second resistance and the fifth switch in an off state, which are coupled in parallel, as compared to an impedance of the circuitry in which the signal has been allowed to flow through the second resistance only, and
an amount of increase in an impedance of the circuitry in which the signal has been allowed to flow through the third inductor is substantially equal to an amount of decrease in an impedance of the circuitry in which the signal has been allowed to flow through the third resistance and the seventh switch in an off state, which are coupled in parallel, as compared to an impedance of the circuitry in which the signal has been allowed to flow through the third resistance only.

12. The switching circuit according to claim 8, further comprising:
a control circuit, wherein
the control circuit is configured to:
bring, in a first operation, the first switch, the second switch, the sixth switch, and the seventh switch to an on state, and the third switch, the fourth switch, the fifth switch, and the eighth switch to an off state;
bring, in a second operation, the third switch, the fourth switch, the fifth switch, and the seventh switch to an on state, and the first switch, the second switch, the sixth switch, and the eighth switch to an off state; and
bring, in a third operation, the third switch, the sixth switch, and the eighth switch to an on state, and the first switch, the second switch, the fourth switch, the fifth switch, and the seventh switch to an off state.

13. The switching circuit according to claim 1, further comprising:
a first circuit provided between the first terminal and the first node, and configured to provide matching between an impedance on a side of the first terminal and an impedance on a side of the first node.

14. The switching circuit according to claim 13, wherein
the first circuit includes at least one of a fourth inductor coupled between the first terminal and the first node, or a first capacitor including a first end coupled to the first terminal and a second end that is grounded.

15. The switching circuit according to claim 1, further comprising:
a second circuit provided between the second terminal and the third node, and configured to provide matching between an impedance on a side of the second terminal and an impedance on a side of the third node.

16. The switching circuit according to claim 15, wherein
the second circuit includes at least one of a fifth inductor coupled between the second terminal and the third node, or a second capacitor including a first end coupled to the second terminal and a second end that is grounded.

17. The switching circuit according to claim 1, further comprising:
a third circuit provided between the third terminal and the fifth node, and configured to provide matching between an impedance on a side of the third terminal and an impedance on a side of the fifth node.

18. The switching circuit according to claim 17, wherein
the third circuit includes at least one of a sixth inductor coupled between the third terminal and the fifth node, or a third capacitor including a first end coupled to the third terminal and a second end that is grounded.

19. The switching circuit according to claim 1, further comprising:
a ninth switch including a first end coupled to the first node and a second end coupled to a sixth node;
a tenth switch and a fourth resistance coupled in parallel between the sixth node and a seventh node;
a fourth terminal coupled to the seventh node;
an eleventh switch including a first end coupled to the sixth node; and
a seventh inductor including a first end coupled to a second end of the eleventh switch and a second end that is grounded.
